(19) United States
(12) Patent Application Publication
(10) Pub. No.: US 2003/0045125 A1
(43) Pub. Date: Mar. 6, 2003

(54) Nitrogen containing plasma annealing method for forming a nitrogenated silicon carbide layer

(75) Inventors: Tien-I Bao, Hsin-Chu (TW); Lain-Jong Li, Hualien (TW); Syun-Ming Jang, Hsing-Chu (TW)

Correspondence Address: TUNG & ASSOCIATES, 838 W. Long Lake Road, Suite 120, Bloomfield Hills, MI, 48302, US

(73) Assignee: Taiwan Semiconductor Manufacturing Co., Ltd.

(21) Appl. No.: 09/946,904

(22) Filed: Sep. 5, 2001

(51) Int. Cl. H01L 21/31; H01L 21/469

(52) U.S. Cl. 438/775; 438/789

(57) ABSTRACT

Within a method for forming a nitrogenated silicon carbide layer there is treated a non-nitrogenated silicon carbide layer with a nitrogen containing plasma. By treating the non-nitrogenated silicon carbide layer with the nitrogen containing plasma, there may be avoided nitrogen containing plasma induced damage to a substrate layer, and in particular a low dielectric constant dielectric material substrate layer, upon which is formed the nitrogenated silicon carbide layer.

### BACKGROUND OF THE INVENTION

1. Field of the Invention

The present invention relates generally to methods for forming silicon carbide layers within microelectronic fabrications. More particularly, the present invention relates to methods for forming nitrogenated silicon carbide layers within microelectronic fabrications.

2. Description of the Related Art

Microelectronic fabrications are formed from microelectronic substrates over which are formed patterned microelectronic conductor layers which are separated by microelectronic dielectric layers.

As microelectronic fabrication integration levels have increased and microelectronic device and patterned microelectronic conductor layer dimensions have decreased, it has become increasingly common in the art of microelectronic fabrication to employ interposed between the patterns of patterned microelectronic conductor layers when fabricating microelectronic fabrications microelectronic dielectric layers formed of comparatively low dielectric constant dielectric materials. Such comparatively low dielectric constant dielectric materials generally have dielectric constants. For comparison purposes, microelectronic dielectric layers formed within microelectronic fabrications from conventional silicon oxide dielectric materials, silicon nitride dielectric materials and silicon oxynitride dielectric materials typically have comparatively high dielectric constants. Similarly, such patterned microelectronic conductor layers having formed interposed between their patterns microelectronic dielectric layers formed of comparatively low dielectric constant dielectric materials are typically formed within microelectronic fabrications while employing damascene methods, including in particular dual damascene methods.

Microelectronic dielectric layers formed of comparatively low dielectric constant dielectric materials are desirable in the art of microelectronic fabrication formed interposed between the patterns of patterned microelectronic conductor layers within microelectronic fabrications insofar as such microelectronic dielectric layers formed of dielectric materials having comparatively low dielectric constants provide microelectronic fabrications which may theoretically operate at higher microelectronic fabrication speeds, with attenuated patterned microelectronic conductor layer parasitic capacitance and attenuated patterned microelectronic conductor layer cross-talk.

Similarly, damascene methods are desirable in the art of microelectronic fabrication for forming patterned microelectronic conductor layers having formed interposed between their patterns microelectronic dielectric layers formed of comparatively low dielectric constant dielectric materials insofar as damascene methods are comparatively simple fabrication methods which may often be employed to fabricate microelectronic structures which are not otherwise practicably accessible in the art of microelectronic fabrication.

While damascene methods are thus desirable in the art of microelectronic fabrication for forming patterned microelectronic conductor layers having formed interposed between their patterns microelectronic dielectric layers formed of comparatively low dielectric constant dielectric materials within microelectronic fabrications, damascene methods are nonetheless not entirely without problems in the art of microelectronic fabrication for forming patterned microelectronic conductor layers having formed interposed between their patterns microelectronic dielectric layers formed of comparatively low dielectric constant dielectric materials within microelectronic fabrications. In that regard, while damascene methods are generally successful for forming patterned microelectronic conductor layers having formed interposed between their patterns microelectronic dielectric layers formed of comparatively low dielectric constant dielectric materials within microelectronic fabrications, such damascene methods often damage the microelectronic dielectric layers formed of the comparatively low dielectric constant dielectric materials.

It is thus desirable in the art of microelectronic fabrication to provide damascene methods which may be employed in the art of microelectronic fabrication for providing patterned microelectronic conductor layers having formed interposed between their patterns microelectronic dielectric layers formed of comparatively low dielectric constant dielectric materials, with attenuated damage to the microelectronic dielectric layers formed of the comparatively low dielectric constant dielectric materials.

It is towards the foregoing object that the present invention is directed.

Various damascene methods have been disclosed in the art of microelectronic fabrication for forming within microelectronic fabrications damascene structures with desirable properties in the art of microelectronic fabrication.

Included among the damascene methods, but not limited among the damascene methods, are damascene methods disclosed within: (1) Yau et al., in U.S. Pat. No. 6,072,227 (a low power method for forming a low dielectric constant dielectric material layer from an organosilane carbon and silicon source material for use as a layer, including but not limited to an etch stop layer and an inter metal dielectric layer, within dual damascene structure within a microelectronic fabrication); and (2) Ye et al., in U.S. Pat. No. 6,080,529 (a plasma etch method which employs a hydrogen and nitrogen containing etchant gas composition for etching within a microelectronic fabrication a low dielectric constant dielectric material layer which may be employed when forming a dual damascene structure within the microelectronic fabrication).

Desirable in the art of microelectronic fabrication are additional damascene methods and materials which may be employed in the art of microelectronic fabrication for providing patterned microelectronic conductor layers having formed interposed between their patterns microelectronic dielectric layers formed of comparatively low dielectric constant dielectric materials, with attenuated damage to the microelectronic dielectric layers.

It is towards the foregoing object that the present invention is directed.

### SUMMARY OF THE INVENTION

A first object of the present invention is to provide a damascene method for forming within a microelectronic fabrication a patterned microelectronic conductor layer having formed interposed between its patterns a microelectronic dielectric layer formed of a comparatively low dielectric constant dielectric material.

A second object of the present invention is to provide a damascene method in accord with the first object of the present invention, wherein the patterned microelectronic conductor layer is formed with attenuated damage to the microelectronic dielectric layer.

A third object of the present invention is to provide a damascene method in accord with the first object of the present invention and the second object of the present invention, wherein the damascene method is readily commercially implemented.

In accord with the objects of the present invention, there is provided by the present invention a method for forming a nitrogenated silicon carbide layer within a microelectronic fabrication. To practice the method of the present invention, there is first provided a substrate. There is then formed over the substrate a non-nitrogenated silicon carbide layer. Finally, there is then annealed the non-nitrogenated silicon carbide layer within a nitrogen containing plasma to form therefrom a nitrogenated silicon carbide layer.

Within the present invention, when the nitrogenated silicon carbide layer is employed as an etch stop layer formed upon a comparatively low dielectric constant dielectric material layer within which is formed a damascene aperture (such as a dual damascene aperture) within a microelectronic fabrication, by forming the nitrogenated silicon carbide layer indirectly incident to a nitrogen containing plasma annealing of a non-nitrogenated silicon carbide layer, rather than directly as a nitrogenated silicon carbide layer (while employing, for example, a chemical vapor deposition (CVD) method or plasma enhanced chemical vapor deposition (PECVD) method which employs a nitrogen source material in addition to a silicon source material and a carbon source material), the comparatively low dielectric constant dielectric material layer experiences attenuated etch related damage when forming thereupon the nitrogenated silicon carbide layer. Thus, the nitrogenated silicon carbide layer may be formed with enhanced adhesion upon the comparatively low dielectric constant dielectric material layer.

Within the present invention, a contiguous patterned conductor interconnect and patterned conductor stud layer may be formed into the damascene aperture, such as a dual damascene aperture which comprises a corresponding trench contiguous with a corresponding via, while employing a blanket conductor layer deposition and planarizing method, preferably a blanket conductor layer deposition and chemical mechanical polish (CMP) planarizing method.

There is provided by the present invention a damascene method for forming within a microelectronic fabrication a patterned microelectronic conductor layer having formed interposed between its patterns a microelectronic dielectric layer formed of a comparatively low dielectric constant dielectric material, wherein the patterned microelectronic conductor layer is formed with attenuated damage to the microelectronic dielectric layer.

The present invention realizes the foregoing object by employing within a damascene method, and for forming a damascene aperture within which may be formed a patterned conductor layer having formed interposed between its patterns a dielectric layer formed of a low dielectric constant dielectric material, an etch stop layer formed of a nitrogenated silicon carbide layer formed incident to a nitrogen containing plasma annealing of a non-nitrogenated silicon carbide layer. When the etch stop layer is formed upon the dielectric layer formed of the low dielectric constant dielectric material, the indirect nitrogen containing plasma annealing method for forming the nitrogenated silicon carbide layer from a non-nitrogenated silicon carbide layer provides for attenuated etching damage in comparison with directly forming a nitrogenated silicon carbide layer while employing a silicon source material, a carbon source material and a nitrogen source material within, for example, a chemical vapor deposition (CVD) method or a plasma enhanced chemical vapor deposition (PECVD) method.

The method in accord with the present invention is readily commercially implemented.

As will be illustrated in greater detail within the context of the Description of the Preferred Embodiments, as set forth below, the method of the present invention employs methods and materials as are otherwise generally known in the art of microelectronic fabrication, but employed within the context of specific process limitations and specific materials limitations to provide the method of the present invention. Since it is thus at least in part a series of specific process limitations and specific materials limitations which provides at least in part the present invention, rather than the existence of methods and materials which provides the present invention, the method of the present invention is readily commercially implemented.

### BRIEF DESCRIPTION OF THE DRAWINGS

The objects, features and advantages of the present invention are understood within the context of the Description of the Preferred Embodiments, as set forth below. The Description of the Preferred Embodiments is understood within the context of the accompanying drawings, which form a material part of this disclosure, wherein:

FIG. 1 and FIG. 2 show a pair of schematic cross-sectional diagrams illustrating the results of progressive stages of forming, in accord with a general embodiment of the present invention which comprises a first preferred embodiment of the present invention, a nitrogenated silicon carbide layer in accord with the present invention.

FIG. 3. FIG. 4 and FIG. 5 show a series of schematic cross-sectional diagrams illustrating the results of progressive stages of forming, in accord with a more specific embodiment of the present invention which comprises a second preferred embodiment of the present invention, a patterned conductor layer formed within a dual damascene aperture defined in part by a nitrogenated silicon carbide layer as an etch stop layer in accord with the present invention.

### DESCRIPTION OF THE PREFERRED EMBODIMENT

There is provided by the present invention a damascene method for forming within a microelectronic fabrication a patterned microelectronic conductor layer having formed interposed between its patterns a microelectronic dielectric layer formed of a comparatively low dielectric constant dielectric material, wherein the patterned microelectronic conductor layer is formed with attenuated damage to the microelectronic dielectric layer.

The present invention realizes the foregoing object by employing within a damascene method, and for forming a damascene aperture within which may be formed a patterned conductor layer having formed interposed between its patterns a dielectric layer formed of a low dielectric constant dielectric material, an etch stop layer formed of a nitrogenated silicon carbide layer formed incident to a nitrogen containing plasma annealing of a non-nitrogenated silicon carbide layer. When the etch stop layer is formed upon the dielectric layer formed of the low dielectric constant dielectric material, the indirect nitrogen containing plasma annealing method for forming the nitrogenated silicon carbide layer from a non-nitrogenated silicon carbide layer provides for attenuated etching damage in comparison with directly forming a nitrogenated silicon carbide layer while employing a silicon source material, a carbon source material and a nitrogen source material within, for example, a chemical vapor deposition (CVD) method or a plasma enhanced chemical vapor deposition (PECVD) method.

The preferred embodiment of the present invention provides particular value within the context of forming, while employing a dual damascene method, and within a semiconductor integrated circuit microelectronic fabrication, a patterned microelectronic conductor layer having formed interposed between its patterns a microelectronic dielectric layer formed of a comparatively low dielectric constant dielectric material. However, the present invention may nonetheless be employed for forming, while employing a dual damascene method, patterned conductor layers within microelectronic fabrications selected from the group including but not limited to integrated circuit microelectronic fabrications, ceramic substrate microelectronic fabrications, solar cell optoelectronic microelectronic fabrications, sensor image array optoelectronic microelectronic fabrications and display image array optoelectronic microelectronic fabrications.

Similarly, while the preferred embodiment of the present invention provides particular value in forming a nitrogenated silicon carbide layer for use as an etch stop layer within a damascene structure within a microelectronic fabrication, the present invention may nonetheless be employed for forming nitrogenated silicon carbide layers for use as various layers within the various microelectronic fabrications noted above.

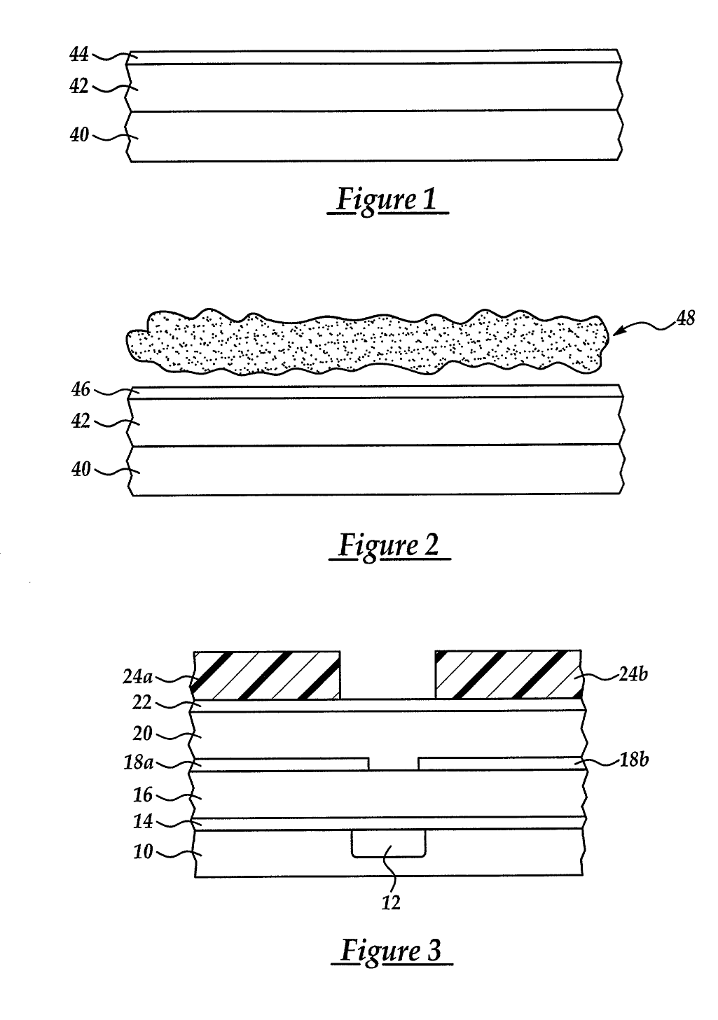

Referring now to FIG. 1 and FIG. 2, there is shown a pair of schematic cross-sectional diagrams illustrating the results of progressive stages of forming, in accord with a general embodiment of the present invention which comprises a first preferred embodiment of the present invention, a nitrogenated silicon carbide layer within a microelectronic fabrication.

Shown in FIG. 1 is a schematic cross-sectional diagram of the microelectronic fabrication at an early stage in its fabrication in accord with the first preferred embodiment of the present invention.

Shown in FIG. 1 is a substrate 40 having formed thereover a blanket dielectric layer 42 in turn having formed thereupon a blanket non-nitrogenated silicon carbide layer 44.

Within the first preferred embodiment of the present invention with respect to the substrate 40, the substrate 40 may be a substrate employed within a microelectronic fabrication selected from the group including but not limited to integrated circuit microelectronic fabrications, ceramic substrate microelectronic fabrications, solar cell optoelectronic microelectronic fabrications, sensor image array optoelectronic microelectronic fabrications and display image array optoelectronic microelectronic fabrications.

Although not specifically illustrated within the schematic cross-sectional diagram of FIG. 1, the substrate 40 may consist of a substrate alone as employed within the microelectronic fabrication, or in an alternative, the substrate 40 may comprise a substrate as employed within the microelectronic fabrication, wherein the substrate has formed thereupon and/or thereover any of several additional microelectronic layers as are conventionally employed within the microelectronic fabrication within which is employed the substrate. Similarly with the substrate alone as employed within the microelectronic fabrication, such additional microelectronic layers may be formed from microelectronic materials selected from the group including but not limited to microelectronic conductor materials, microelectronic semiconductor materials and microelectronic dielectric materials.

In addition, and although also not specifically illustrated within the schematic cross-sectional diagram of FIG. 1, the substrate 40, typically and preferably, but not exclusively, when the substrate 40 consists of or comprises a semiconductor substrate as employed within a semiconductor integrated circuit microelectronic fabrication, has formed therein and/or thereupon microelectronic devices as are similarly also conventional within the microelectronic fabrication within which is employed the substrate 40. Such microelectronic devices may be selected from the group including but not limited to resistors, transistors, diodes and capacitors.

Within the preferred embodiment of the present invention with respect to the blanket dielectric layer 42, and while the blanket dielectric layer 42 may be formed from any of several dielectric materials, preferably the blanket dielectric layer is formed from any of several comparatively low dielectric constant dielectric materials as are conventional or unconventional in the art of microelectronic fabrication, including but not limited to spin-on-glass (SOG) dielectric materials, spin-on-polymer (SOP) dielectric materials, nanoporous dielectric materials, amorphous carbon dielectric materials and fluorosilicate glass (FSG) dielectric materials. More preferably, the present invention provides particular value under circumstances where the blanket dielectric layer 42 is formed of a porous dielectric material, and in particular a nanoporous dielectric material, generally having a particularly low dielectric constant in a range of from about 1.2 to about 5. Typically and preferably, the blanket dielectric layer 42 is formed to a thickness of from about 100 to about 10000 angstroms.

Finally, within the first preferred embodiment of the present invention with respect to the blanket non-nitrogenated silicon carbide layer 44, and although any of several methods may be employed for forming the blanket non-nitrogenated silicon carbide layer 44 (including but not limited to chemical vapor deposition (CVD) methods, plasma enhanced chemical vapor deposition (PECVD) methods and physical vapor deposition (PVD) sputtering methods), for the first preferred embodiment of the present invention, the blanket non-nitrogenated silicon carbide layer 44 is typically and preferably formed employing a plasma enhanced chemical vapor deposition (PECVD) method employing an organosilane silicon and carbon source material, without a nitrogen source material. Although any of several organosilanes may be employed as the silicon and carbon source material, including but not limited to those disclosed within Yau et al., in U.S. Pat. No. 6,072,227, as cited within the Description of the Related Art (all of which related art is incorporated herein by reference), for the first preferred embodiment of the present invention the organosilane silicon and carbon source material is typically and preferably a methyl silane, such as monomethyl silane, dimethyl silane, trimethyl silane of tetramethyl silane, but more preferably trimethyl silane or tetramethyl silane.

Typically and preferably, the plasma enhanced chemical vapor deposition (PECVD) method also employs with respect to forming the blanket non-nitrogenated silicon carbide layer 44 over an eight or twelve inch diameter substrate: (1) a reactor chamber pressure of from about 1 m to about 100 torr; (2) a radio frequency source power of from about 100 to about 5000 watts at a source radio frequency of 13.56 MHZ, with a bias power; (3) a substrate 10 temperature of from about 100 to about 800 degrees centigrade; (4) a tetramethyl silane silicon and carbon source material flow rate of from about 10 to about 10000 standard cubic centimeters per minute (sccm).

Referring now to FIG. 2, there is shown a schematic cross-sectional diagram illustrating the results of further processing of the microelectronic fabrication whose schematic cross-sectional diagram is illustrated in FIG. 1.

Shown in FIG. 2 is a schematic cross-sectional diagram of a microelectronic fabrication otherwise equivalent to the microelectronic fabrication whose schematic cross-sectional diagram is illustrated in FIG. 1, but wherein the blanket non-nitrogenated silicon carbide layer 44 has been treated with a nitrogen containing plasma 48 to form therefrom a blanket nitrogenated silicon carbide layer 46.

Within the first preferred embodiment of the present invention, the nitrogen containing plasma 48 may be formed from any of several nitrogen containing species, including but not limited to nitrogen, ammonia, hydrazine and hydrazoic acid.

When treating the blanket non-nitrogenated silicon carbide layer 44 within the nitrogen containing plasma 48 to form therefrom the blanket nitrogenated silicon carbide layer 46 upon an eight inch diameter substrate 40, the nitrogen containing plasma 48 also employs: (1) a reactor chamber pressure of from about 1 m to about 100 torr; (2) a radio frequency power of from about 50 to about 5000 watts; (3) a substrate 10 (and non-nitrogenated silicon carbide layer 44) temperature of from about 100 to about 500 degrees centigrade; and (4) a nitrogen source material flow rate of from about 10 to about 10000 standard cubic centimeters per minute (sccm). Under such conditions, there is typically and preferably incorporated from about 0.01% to about 80% atomic percent nitrogen into the blanket non-nitrogenated silicon carbide layer 44 when forming therefrom the blanket nitrogenated silicon carbide layer 46.

As is understood by a person skilled in the art, by employing when forming the blanket nitrogenated silicon carbide layer 46 as illustrated within the schematic cross-sectional diagram of FIG. 2 the nitrogen containing plasma 48 treatment of the blanket non-nitrogenated silicon carbide layer 44 as illustrated within the schematic cross-sectional diagram of FIG. 1, rather than forming the blanket nitrogenated silicon carbide layer 46 directly while employing, for example, a chemical vapor deposition (CVD) method or a plasma enhanced chemical vapor deposition (PECVD) method which simultaneously employs a silicon source material a carbon source material and a nitrogen source material, there is avoided, when forming the nitrogenated silicon carbide layer 46 in accord with the first preferred embodiment of the present invention, nitrogen induced damage to the blanket dielectric layer 42. Such nitrogen induced damage to the blanket dielectric layer 42 may otherwise provide for compromised adhesion thereupon of the blanket nitrogenated silicon carbide layer 46.

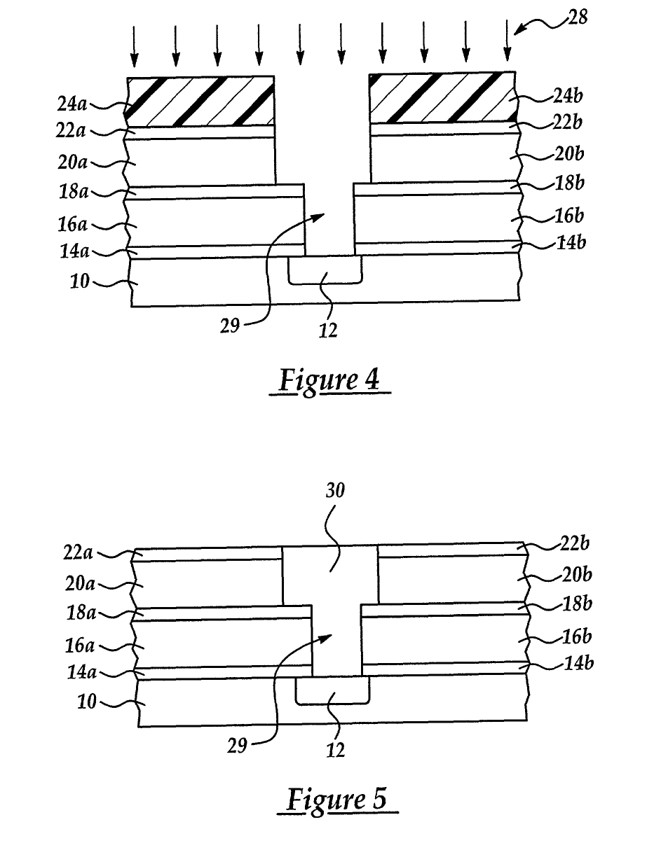

Referring now to FIG. 3 to FIG. 5, there is shown a series of schematic cross-sectional diagrams illustrating the results of progressive stages in forming, in accord with a more specific embodiment of the present invention, which comprises a second preferred embodiment of the present invention, a patterned microelectronic conductor layer within a microelectronic fabrication while employing a dual damascene method.

Shown in FIG. 3 is a schematic cross-sectional diagram of the microelectronic fabrication at an early stage in its fabrication in accord with the second preferred embodiment of the present invention.

Shown in FIG. 3, in a first instance, is a substrate 10 having formed therein a contact region 12.

Within the second preferred embodiment of the present invention with respect to the substrate 10, the substrate 10 is analogous or equivalent to the substrate 40 as illustrated within the schematic cross-sectional diagram of FIG. 1.

Within the second preferred embodiment of the present invention with respect to the contact region 12, the contact region 12 is typically and preferably either: (1) a semiconductor contact region, particularly under circumstances where the substrate 10 consists of or comprises a semiconductor substrate as employed within a semiconductor integrated circuit microelectronic fabrication; or (2) a conductor contact region, under circumstances where the substrate 10 is employed within any of the several microelectronic fabrications as noted above with respect to the first preferred embodiment of the present invention.

Shown also within the schematic cross-sectional diagram of FIG. 1, and formed upon the substrate 10 having formed therein the contact region 12, is a series of layers comprising: (1) a blanket first etch stop/liner layer 14 formed upon the substrate 10 having formed therein the contact region 12; (2) a blanket first dielectric layer 16 formed upon the blanket first etch stop/liner layer 14; (3) a pair of patterned second etch stop layers 18a and 18b formed upon the blanket first dielectric layer 16; (4) a blanket second dielectric layer 20 formed upon exposed portions of the blanket first dielectric layer 16 and the patterned second etch stop layers 18a and 18b; (5) a blanket third etch stop/planarizing stop layer 22 formed upon the blanket second dielectric layer 20; and (6) a pair of patterned photoresist layers 24a and 24b formed upon the blanket third etch stop/planarizing stop layer 22.

Within the preferred embodiment of the present invention with respect to the blanket first etch stop/liner layer 14, the pair of patterned second etch stop layers 18a and 18b and the blanket third etch stop/planarizing stop layer 22, at least one of the blanket first etch stop/liner layer 14, the pair of patterned second etch stop layers 18a and 18b and the blanket third etch stop/planarizing stop layer 22 is formed of as a nitrogenated silicon carbide layer formed analogously or equivalently with the blanket nitrogenated silicon carbide layer 46 as illustrated within the schematic cross-sectional diagram of FIG. 2.

Typically and preferably, at least both of the pair of patterned second etch stop layers 18a and 18b and the blanket third etch stop/planarizing stop layer 22 are formed as nitrogenated silicon carbide layers in accord with the first preferred embodiment of the present invention.

Typically and preferably, the blanket first etch stop/liner layer 14 is formed to a thickness of from about 50 to about 5000 angstroms, the pair of patterned second etch stop layers 18a and 18b is formed to a thickness of from about 50 to about 5000 angstroms and the blanket third etch stop/planarizing stop layer 22 is formed to a thickness of from about 50 to about 5000 angstroms.

Within the preferred embodiment of the present invention with respect to the blanket first dielectric layer 16 and the blanket second dielectric layer 20, the blanket first dielectric layer 16 and the blanket second dielectric layer 22 may be formed from any of several comparatively low dielectric constant dielectric materials as are employed for forming the blanket dielectric layer 42 as illustrated within the schematic cross-sectional diagrams of FIG. 1 and FIG. 2. Typically and preferably, each of the blanket first dielectric layer 16 and the blanket second dielectric layer 20 is formed to a thickness of from about 1000 to about 10000 angstroms and each of the blanket first dielectric layer 16 and the blanket second dielectric layer 20 is formed of the same dielectric material, although such limitation is not required within the present invention and the preferred embodiment of the present invention.

Finally, within the second preferred embodiment of the present invention with respect to the pair of patterned photoresist layers 24a and 24b, the pair of patterned photoresist layers 24a and 24b may be formed from any of several photoresist materials as are conventional in the art of microelectronic fabrication, including but not limited to photoresist materials selected from the general groups of photoresist materials including but not limited to positive photoresist materials and negative photoresist materials. Typically and preferably, each of the pair of patterned photoresist layers 24a and 24b is formed to a thickness of from about 100 to about 10000 angstroms.

As is understood by a person skilled in the art, the pair of patterned photoresist layers 24a and 24b defines the location of an areally enclosed trench, of linewidth from about 0.01 to about 0.35 microns, to be formed through the blanket third etch stop/planarizing stop layer 22 and the blanket second dielectric layer 20, while the pair of patterned second etch stop layers 18a and 18b defines the location of an areally enclosed via, of linewidth from about 0.01 to about 0.35 microns, to be formed through the blanket first dielectric layer 16 and the blanket first etch stop/liner layer and overlapped by the trench.

Referring now to FIG. 4, there is shown a schematic cross-sectional diagram illustrating the results of further processing of the microelectronic fabrication whose schematic cross-sectional diagram is illustrated in FIG. 3.

Shown in FIG. 4 is a schematic cross-sectional diagram of a microelectronic fabrication otherwise equivalent to the microelectronic fabrication whose schematic cross-sectional diagram is illustrated in FIG. 3, but wherein there has been etched the blanket third etch stop/planarizing stop layer 22, the blanket second dielectric layer 20, the blanket first dielectric layer 16 and the blanket first etch stop/liner layer 14 to form a corresponding pair of patterned third etch stop/planarizing stop layers 22a and 22b, a corresponding pair of patterned second dielectric layers 20a and 20b, a corresponding pair of patterned first dielectric layers 16a and 16b and a corresponding pair of patterned first etch stop/liner layers 14a and 14b, while employing the pair of patterned photoresist layers 24a and 24b and the pair of patterned second etch stop layers 18a and 18b as etch mask layers, in conjunction with a second etching plasma 28. As is illustrated within the schematic cross-sectional diagram of FIG. 4, the foregoing series of patterned layers defines a dual damascene aperture 29 which accesses the contact region 12.

As is yet further understood by a person skilled in the art: (1) the pair of patterned first etch stop/liner layers 14a and 14b, the pair of patterned first dielectric layers 16a and 16b and in part the pair of patterned second etch stop layers 18a and 18b define a via within the dual damascene aperture 29; and (2) the pair of patterned second dielectric layers 20a and 20b and the pair of patterned third etch stop/planarizing stop layers 22a and 22b define a trench within the dual damascene aperture 29.

Within the present invention and the preferred embodiment of the present invention, the etching plasma 28 employs a series of etchant gas compositions as is appropriate to the materials from which are formed the blanket third etch stop/planarizing stop layer 22, the blanket second dielectric layer 20, the blanket first dielectric layer 16 and the blanket first etch stop/liner layer 14.

Referring now to FIG. 5, there is shown a schematic cross-sectional diagram illustrating the results of further processing of the microelectronic fabrication whose schematic cross-sectional diagram is illustrated in FIG. 4.

Shown in FIG. 5 is a schematic cross-sectional diagram of a microelectronic fabrication otherwise equivalent to the microelectronic fabrication whose schematic cross-sectional diagram is illustrated in FIG. 4, but wherein, in a first instance, the pair of patterned photoresist layers 24a and 24b has been stripped from the pair of patterned third etch stop/planarizing stop layers 22a and 22b.

The pair of patterned photoresist layers 24a and 24b may be stripped from the pair of patterned third etch stop/planarizing stop layers 22a and 22b while employing methods as are conventional in the art of microelectronic fabrication, including but not limited to wet chemical stripping methods and dry plasma stripping methods.

Finally, there is also shown within the schematic cross-sectional diagram of FIG. 5 the results of forming within the dual damascene aperture 29 a contiguous patterned conductor interconnect and patterned conductor stud layer 30.

Within the second preferred embodiment of the present the contiguous patterned conductor interconnect and patterned conductor stud layer 30 may be formed employing methods and materials as are conventional in the art of microelectronic fabrication, which will typically and preferably include chemical mechanical polish (CMP) planarizing methods. Typically and preferably, the contiguous patterned conductor interconnect and patterned conductor stud layer 30 will have formed as its lower portion a conformal barrier layer such as to inhibit interdiffusion of the contiguous patterned conductor interconnect and patterned conductor stud layer 30 with other patterned layers and structures which it adjoins within the microelectronic fabrication whose schematic cross-sectional diagram is illustrated in FIG. 5. Typically and preferably, the contiguous patterned conductor interconnect and patterned conductor stud layer 30 is formed of a copper or copper alloy conductor material, although other conductor materials may also be employed.

Upon forming the microelectronic fabrication whose schematic cross-sectional diagram is illustrated in FIG. 5, there is formed a microelectronic fabrication in accord with the second preferred embodiment of the present invention. The microelectronic fabrication has formed therein, while employing a dual damascene method, a patterned conductor having formed interposed between its patterns a dielectric layer formed of a comparatively low dielectric constant dielectric material, with attenuated damage to the dielectric layer. The second preferred embodiment of the present invention realizes the foregoing object by employing when forming an etch stop layer upon the dielectric layer formed of the comparatively low dielectric constant dielectric material, the etch stop layer formed of a nitrogenated silicon carbide material formed through a nitrogen containing plasma annealing of a non-nitrogenated silicon carbide material. Thus, by avoiding within the present invention when forming a nitrogenated silicon carbide layer upon a dielectric layer formed of a comparatively low dielectric constant dielectric material the presence of a nitrogen source material, there is attenuated etching of the dielectric layer when forming thereupon the nitrogenated silicon carbide layer. Similarly, there is also realized enhanced adhesion of the nitrogenated silicon carbide layer to the dielectric layer.

As is understood by a person skilled in the art, the preferred embodiment of the present invention is illustrative of the present invention rather than limiting of the present invention. Revisions and modifications may be made to methods, materials, structures and dimensions through which is provided a nitrogenated silicon carbide layer or a patterned conductor layer in accord with the preferred embodiments of the present invention, which still providing a method for forming a nitrogenated silicon carbide layer and a method for forming a patterned conductor layer in accord with the present invention, further in accord with the accompanying claims.

What is claimed is:

1. A method for forming a nitrogenated silicon carbide layer comprising:
providing a substrate;
forming over the substrate a non-nitrogenated silicon carbide layer; and
annealing the non-nitrogenated silicon carbide layer within a nitrogen containing plasma to form therefrom a nitrogenated silicon carbide layer.

2. The method of claim 1 wherein the non-nitrogenated silicon carbide layer is formed employing a chemical vapor deposition method (CVD) method which employs an organosilane carbon and silicon source material absent a nitrogen source material.

3. The method of claim 1 wherein the non-nitrogenated silicon carbide layer is formed to a thickness of from about 100 to about 5000 angstroms.

4. The method of claim 1 wherein the nitrogen containing plasma employs a nitrogen source material selected from the group consisting of nitrogen, ammonia, hydrazine and hydrazoic acid.

5. The method of claim 1 further comprising forming over the substrate a comparatively low dielectric constant dielectric material layer prior to forming over the substrate the non-nitrogenated silicon carbide layer, where the non-nitrogenated silicon carbide layer is formed upon the comparatively low dielectric constant dielectric material layer.

6. The method of claim 5 wherein by forming the nitrogenated silicon carbide layer incident to nitrogen plasma annealing of the non-nitrogenated silicon carbide layer, there is provided enhanced adhesion of the nitrogenated silicon carbide layer to the comparatively low dielectric constant dielectric material layer.

7. The method of claim 5 wherein the comparatively low dielectric constant dielectric material layer is formed from a dielectric material selected from the group consisting of spin-on-glass (SOG) dielectric materials, spin-on-polymer (SOP) dielectric materials, nanoporous dielectric materials, amorphous carbon dielectric materials and fluorosilicate glass dielectric materials.

8. The method of claim 5 wherein the comparatively low dielectric constant dielectric material layer is formed to a thickness of from about 1000 to about 10000 angstroms.

9. A method for forming a patterned conductor layer comprising:
providing a substrate;
forming over the substrate a dielectric layer;
forming upon the dielectric layer a non-nitrogenated silicon carbide layer;
annealing the non-nitrogenated silicon carbide layer within a nitrogen containing plasma to form therefrom a nitrogenated silicon carbide layer formed upon the dielectric layer;
forming through at least the nitrogenated silicon carbide layer an aperture; and
forming into the aperture a patterned conductor layer.

10. The method of claim 9 wherein the non-nitrogenated silicon carbide layer is formed employing a chemical vapor deposition method (CVD) method which employs an organosilane carbon and silicon source material absent a nitrogen source material.

11. The method of claim 9 wherein the non-nitrogenated silicon carbide layer is formed to a thickness of from about 100 to about 5000 angstroms.

12. The method of claim 9 wherein the nitrogen containing plasma employs a nitrogen source material selected from the group consisting of nitrogen, ammonia, hydrazine and hydrazoic acid.

13. The method of claim 9 wherein by forming the nitrogenated silicon carbide layer incident to nitrogen plasma annealing of the non-nitrogenated silicon carbide layer, there is provided enhanced adhesion of the nitrogenated silicon carbide layer to the dielectric layer.

14. The method of claim 9 wherein the dielectric layer is formed from a comparatively low dielectric constant dielectric material selected from the group consisting of spin-on-glass (SOG) dielectric materials, spin-on-polymer (SOP) dielectric materials, nanoporous dielectric materials, amorphous carbon dielectric materials and fluorosilicate glass dielectric materials.

15. The method of claim 9 wherein the dielectric layer is formed to a thickness of from about 1000 to about 10000 angstroms.
